(19) United States
(12) Patent Application Publication
(10) Pub. No.: US 2018/0062058 A1
(43) Pub. Date: Mar. 1, 2018

(54) LIGHT-EMITTING APPARATUS AND ILLUMINATION APPARATUS

(71) Applicant: PANASONIC INTELLECTUAL PROPERTY MANAGEMENT CO., LTD., Osaka (JP)

(72) Inventors: Masumi ABE, Osaka (JP); Naoki TAGAMI, Osaka (JP); Toshiaki KURACHI, Kyoto (JP)

(73) Assignee: PANASONIC INTELLECTUAL PROPERTY MANAGEMENT CO., LTD., Osaka (JP)

(21) Appl. No.: 15/666,935

(22) Filed: Aug. 2, 2017

(30) Foreign Application Priority Data
Aug. 23, 2016 (JP) 2016-163140

(51) Int. Cl. H01L 33/64; C09K 11/02; C09K 11/62; C09K 11/77; H01L 33/56; H01L 33/50; H01L 33/60; H01L 33/32; H01L 33/62; H01L 25/075; F21V 29/75; F21V 3/02; F21V 7/22; F21V 29/89; F21V 23/02

(52) U.S. Cl. CPC H01L 33/644; C09K 11/0883; C09K 11/62; C09K 11/7706; H01L 33/56; H01L 33/502; H01L 33/60; H01L 33/32; H01L 33/62; H01L 25/0753; F21V 29/75; F21V 3/02; F21V 7/22; F21V 29/89; F21V 23/023; C09K 11/025

(57) ABSTRACT

A light-emitting apparatus is provided. The light-emitting apparatus includes: a substrate; an LED chip on the substrate; and a sealant which seals the LED chip. The sealant includes at least 0.05 wt % oxide of a transition metal as an additive for inhibiting deterioration of a base material of the sealant. Additionally or alternatively, the sealant includes at least one of a metal salt of a transition metal and an organic complex of a transition metal, as the additive.

### CROSS REFERENCE TO RELATED APPLICATION

This application claims the benefit of priority of Japanese Patent Application Number 2016-163140 filed on Aug. 23, 2016, the entire content of which is hereby incorporated by reference.

### BACKGROUND

### 1. Technical Field

The present disclosure relates to a light-emitting apparatus and an illumination apparatus using the same.

### 2. Description of the Related Art

Conventionally, a light-emitting apparatus is known, which emits white light by sealing a light emitting diode (LED) chip with a sealant which contains phosphor. As such a light-emitting apparatus, Japanese Unexamined Patent Application Publication No. 2010-56398 discloses a light-emitting apparatus which has, what is known as, an SMD (Surface Mount Device) structure.

### SUMMARY

Inhibiting deterioration of the sealant is a challenge of the light-emitting apparatus as described above. In particular, since the sealant increases in temperature during illumination of an LED, a challenge of the light-emitting apparatus is to inhibit the deterioration of the sealant in high temperature environment, to be more specific, to improve the heat resistance of the sealant.

The present disclosure provides a light-emitting apparatus and an illumination apparatus which include a sealant having an improved heat resistance.

A light-emitting apparatus according to one aspect of the present disclosure includes: a substrate; a light-emitting element on the substrate; and a sealant which seals the light-emitting element, wherein the sealant includes at least 0.05 wt % oxide of a transition metal as an additive for inhibiting deterioration of a base material of the sealant.

A light-emitting apparatus according to one aspect of the present disclosure includes: a substrate; a light-emitting element on the substrate; and a sealant; which seals the light-emitting element, wherein the sealant includes at least one of a metal salt of a transition metal and an organic complex of a transition metal, as an additive for inhibiting deterioration of a base material of the sealant.

An illumination apparatus according to one aspect of the present disclosure includes: the light-emitting apparatus according to any of the above aspects; and a lighting apparatus which supplies the light-emitting apparatus with power for causing the light-emitting apparatus to emit light.

A light-emitting apparatus and an illumination apparatus according to one aspect of the present disclosure include a sealant that has an improved heat resistance.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is an external perspective view of a light-emitting apparatus according to Embodiment 1 of the present disclosure;

FIG. 2 is a plan view of the light-emitting apparatus according to Embodiment 1;

FIG. 3 is a plan view illustrating an internal structure of the light-emitting apparatus according to Embodiment 1;

FIG. 4 is a schematic cross-sectional view of the light-emitting apparatus, taken along a line IV-IV in FIG. 2;

FIG. 5 is a first diagram showing test results on heat resistance of sealants;

FIG. 6 is a second diagram showing test results on heat resistance of sealants;

FIG. 7 is a cross-sectional view of a light emitting apparatus according to Embodiment 2 of the present disclosure;

FIG. 8 is a schematic view illustrating a structure of a first sealing layer;

FIG. 9 is a schematic view illustrating a structure of a second sealing layer;

FIG. 10 is a cross-sectional view of an illumination apparatus according to Embodiment 3 of the present disclosure; and

FIG. 11 is an external perspective view of the alumination apparatus and its peripheral components according to Embodiment 3.

### DETAILED DESCRIPTION OF THE EMBODIMENTS

Hereinafter, a light-emitting apparatus, etc., according to embodiments of the present disclosure are described, with reference to the accompanying drawings. The embodiments described below are each generic and specific example of the present disclosure. Values, shapes, materials, components, and arrangement and connection between the components shown in the following embodiments are merely by way of illustration and not intended to limit the present disclosure. Moreover, among the components in the embodiments below, components not recited in any one of the independent claims defining the most generic part of the inventive concept of the present disclosure are described as arbitrary components.

Figures are schematic views and do not necessarily strictly Illustrate the present disclosure. In the figures, the same reference sign is used to refer to substantially the same configuration, and duplicate description may be omitted or simplified.

### Embodiment 1

[Configuration of Light-Emitting Apparatus]

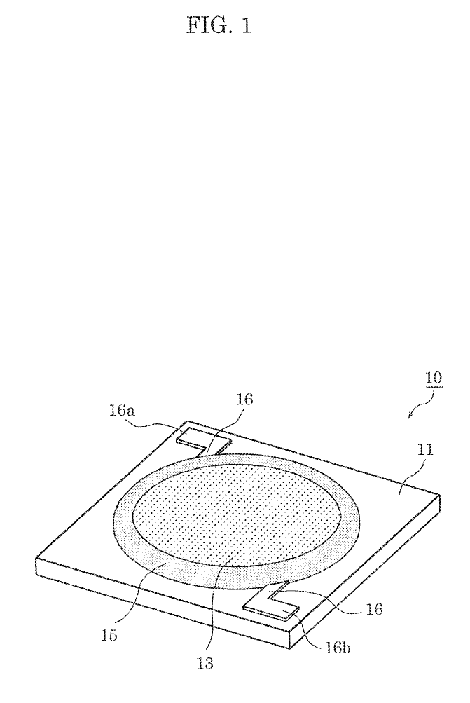

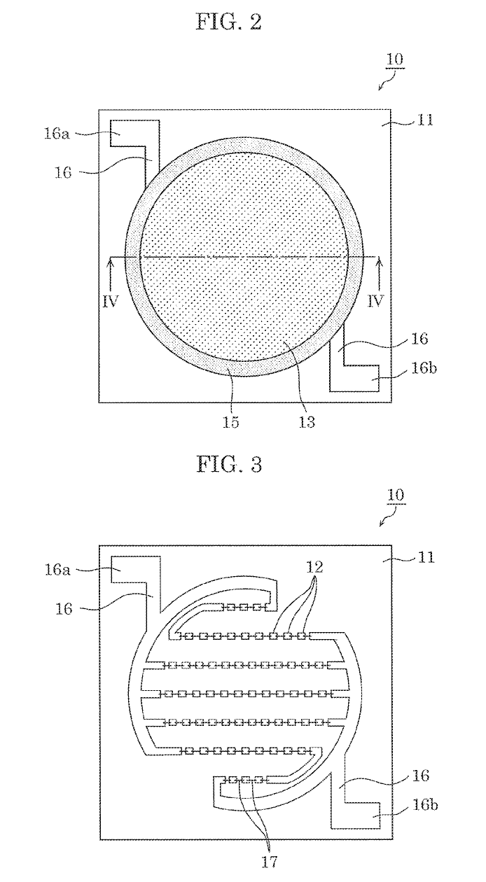

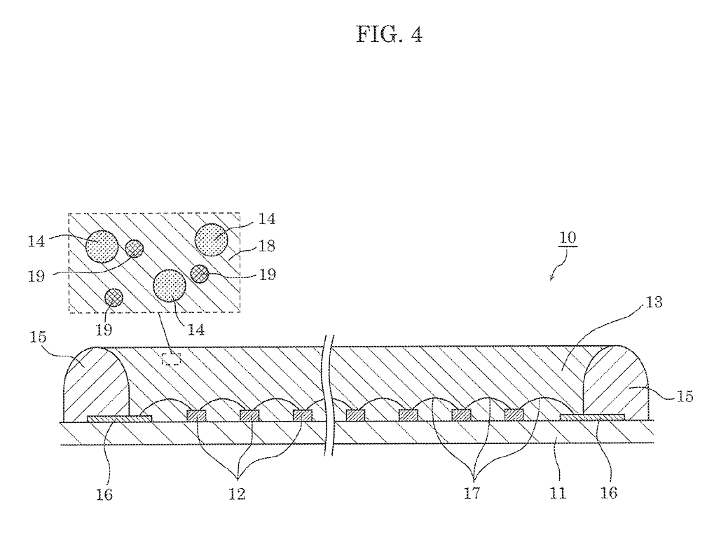

First, a configuration of a light-emitting apparatus according to Embodiment 1 of the present disclosure is described, with reference to the accompanying drawings. FIG. 1 is an external perspective view of the light-emitting apparatus according to Embodiment 1. FIG. 2 is a plan view of the light-emitting apparatus according to Embodiment 1. FIG. 3 is a plan view illustrating an internal structure of the light-emitting apparatus according to Embodiment 1. FIG. 4 is a schematic cross-sectional view of the light-emitting apparatus, taken along a line IV-IV in FIG. 2.

Note that FIG. 3 is a plan view of the light-emitting apparatus from which sealant 13 and dam member 15 in FIG. 2 are removed, illustrating the internal structure, such as arrangement of LED chips 12 and an interconnect pattern. In FIG. 4, the shapes and particle sizes of yellow phosphor 14 and additive 19 are not strict and are schematic.

As illustrated in FIGS, 1 through 4, light-emitting apparatus 10 according to Embodiment 1 includes substrate 11, LED chips 12, sealant 13, and dam member 15.

Light-emitting apparatus 10 is, what is known as, a COB (chip-on-board) LED module in which LED chips 12 are directly mounted on substrate 11.

Substrate 11 has interconnect regions where lines 16 are disposed. Lines 16 (and electrodes 16a and 16b) are formed using metal for supplying LED chips 12 with power. Substrate 11 is, for example, a metal base substrate or a ceramic substrate. Alternatively, substrate 11 may be a resin substrate which includes resin as a base material.

If substrate 11 is a ceramic substrate, the ceramic substrate is an alumina substrate which includes aluminum oxide (alumina), or an aluminum nitride substrate which includes aluminum nitride, for example. If substrate 11 is a metal base substrate, an aluminum alloy substrate, an iron alloy substrate, a copper alloy substrate, or the like, which has, for example, an insulating film formed on its surface is employed as the metal base substrate. If substrate 11 is a resin substrate, for example, a glass-epoxy substrate which includes fiberglass and an epoxy resin is employed as the resin substrate.

For example, a substrate having a high optical reflectance (e.g., optical reflectance of 90% or more) may be employed as substrate 11. Employing a substrate having high optical reflectance as substrate 11 allows light emitted by LED chips 12 to be reflected by the surface of substrate 11. As a result, the efficiency of light-emitting apparatus 10 in extracting light is enhanced. Examples of such a substrate include a white ceramic substrate which includes alumina as a base material.

Alternatively, a light-transmissive substrate having high light-transmittance may be employed as substrate 11. Examples of such a substrate include a light-transmissive ceramic substrate which includes polycrystalline alumina or aluminum nitride, a transparent glass substrate which includes glass, a quartz substrate which includes quartz, a sapphire substrate which includes sapphire, and a transparent resin substrate which includes a transparent resin material.

While substrate 11 is in a rectangular shape in Embodiment 1, it should be noted that substrate 11 may be in any other shape such as a circular shape.

LED chip 12 is one example of a light-emitting element, and is a blue LED chip which emits blue light. As LED chip 12, for example, a gallium-nitride-based LED chip which includes InGaN-based material and has a center wavelength (a peak wavelength of emission spectrum) of 430 nm or greater and 470 nm or less is employed. Note that light-emitting apparatus 10 may include at least one LED chip 12.

Lines of the light-emitting elements, each element configured of LED chip 12, are disposed on substrate 11. As illustrated in FIG. 3, structurally, seven lines of light-emitting elements are disposed on substrate 11 so as to conform to a circular shape.

Five lines of light-emitting elements, each line including twelve LED chips 12 connected in series, are electrically disposed on substrate 11. The five lines of light-emitting elements are connected in parallel, and emit light as power is supplied between electrode 16a and electrode 16b.

Moreover, Chip To Chip electrical interconnection is established, mainly by bonding wires 17, between LED chips 12 connected in series (some of LED chips 12 are electrically connected via lines 16). Bonding wires 17 are electrically and structurally connected to LED chips 12 to supply them with power. Metallic materials from which bonding wires 17, lines 16, and electrodes 16a and 16b) mentioned above are formed are, for example, gold (Au), silver (Ag), or copper (Cu), etc.

Dam member 15 is for damming up sealant 13 disposed on substrate 11. For example, a thermoset resin, a thermoplastic resin, or the like which has insulation properties is employed for dam member 15. More specifically, a silicone resin, a phenolic resin, an epoxy resin, a Bismaleimide-Triazine resin, a polyphthalamide (PPA) resin, or the like is employed for darn member 15.

Desirably, dam member 15 has optical reflectivity in order to enhance the efficiency of light-emitting apparatus 10 in extracting light. Thus, a white-colored resin (what is known as a white resin) is employed for dam member 15 in Embodiment 1. Note that dam member 15 may include particles of TiO₂, Al₂O₃, ZrO₂, MgO, etc., in order to enhance the optical reflectivity of dam member 15.

In light-emitting apparatus 10, dam member 15 is formed in an annular shape surrounding LED chips 12 in a top view. Sealant 13 is disposed in the area surrounded by dam member 15. Note that dam member 15 may be formed in an annular shape having a rectangular outline.

Sealant 13 seals LED chips 12. More specifically, sealant 13 seals LED chips 12, bonding wires 17, and portions of lines 16. Sealant 13 includes base material 18, yellow phosphor 14 and additive 19.

Base material 18 of sealant 13 is a light-transmissive resin material. The light-transmissive resin material is, for example, a methyl-based silicone resin. However, the light-transmissive resin material may be an epoxy resin or a urea resin, for example.

Sealant 13 includes yellow phosphor 14 and additive 19 (shown in FIG. 4). Although not shown, sealant 13 may also include a filler such as silica. Note that sealant 13 may be free from phosphor such as yellow phosphor 14, and may be disposed for the purposes mainly of protection of LED chips 12.

Yellow phosphor 14 is one example of the phosphor (phosphor particles), and emits light when excited by light emitted by LED chips 12. Yellow phosphor 14, specifically, emits yellow phosphor light. For example, yttrium aluminum garnet (YAG)-based phosphor is employed as yellow phosphor 14.

A portion of blue light emitted by LED chips 12 is wavelength-converted into yellow light by yellow phosphor 14 included in sealant 13. Then, a portion of the blue light not absorbed in yellow phosphor 14 and the yellow light obtained by the wavelength-conversion by yellow phosphor 14 are diffused and mixed in sealant 13. This allows white light to be emitted from sealant 13.

Sealant 13 contains additive 19 to inhibit deterioration (oxidative degradation) of the light-transmissive resin material which is base material 18 of sealant 13. As additive 19, for example, a material having oxygen storage capacity and a property of chemically bonding with SiO is employed. A radical scavenger may be employed as additive 19.

Additive 19 is, for example, a compound of a transition metal. Additive 19 is, specifically, an oxide of a transition metal, a metal salt (metallic soap) of a transition metal, or an organic complex of a transition metal, etc. The transition metals are elements from group 3 elements to group 11 elements. The transition metals include a rare earth element. Note that additive 19 is, unlike yellow phosphor 14, not excitable by the light emitted by LED chips 12. Stated differently, additive 19 emits no light.

[Heat Resistance Test on Sealants Having Additive Added Thereto]

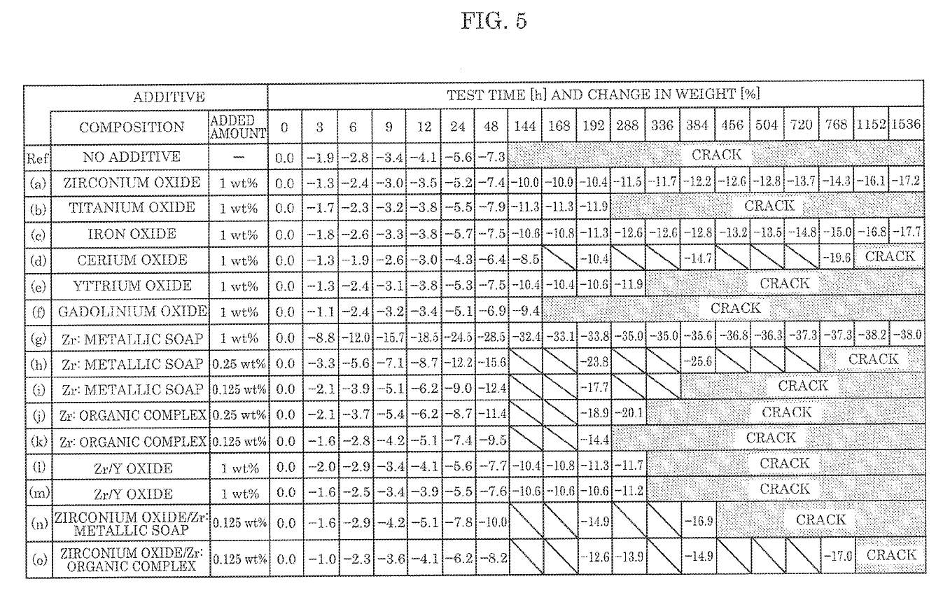

In recent years, an increase of luminance of LED chips 12 is increasing a temperature load on sealant 13. Thus, it is a challenge to inhibit the deterioration of sealant 13 in high temperature environment, to be more specific, to improve the heat resistance of sealant 13. Hence, the inventors have tested the heat resistance of sealants 13 when additive 19 is added to base material 18 of sealant 13. FIG. 5 is a first diagram showing test results on heat resistance of sealants 13.

FIG. 5 shows results obtained by leaving standing test plates (test sealants 13. Hereinafter, also simply referred to as plates) in environment of 260 degrees Celsius, wherein the test plates include, as the base materials of the sealants, OE-6351 (silicone resin) produced by Dow Corning Toray, and have materials (a) to (o) in FIG. 5 added, as additives, to the sealants. In FIG. 5, amounts of change in weight of each of the plates relative to an initial weight are indicated in percentage, and time zones where an amount of change in weight is noted are determined that no crack is developed, that is, the plate is not deteriorated. Stated differently, a plate is determined to be deteriorated after a moment the development of cracks is observed. Note that the reduction of weight of each plate shown in FIG. 5 is attributed to reduction of hydrocarbon contained as a side chain in the silicone resin. The reduction of hydrocarbon (reduction of weight) means progression of oxidative degradation.

The plate designated by the symbol Ref on the uppermost row in FIG. 5 is formed of base material 18 only, free from additive 19. Development of cracks is observed in plate Ref after 144 hours from the start of the test.

[Specific Examples of Additive: Oxide of Transition Metal]

In contrast, for example, the plates (a) to (f) are the same as plate Ref, except that the plates (a) to (f) include an oxide of a transition metal as additive 19.

The plate (a) includes 1.0 wt % zirconium oxide (ZrO₂: Zr-C20 produced by Taki Chemical Co., Ltd.) as additive 19. No crack was developed in the plate (a) even after 1536 hours from the start of the test, indicating that the plate (a) has an improved heat resistance over plate Ref. Note that zirconium is a group 4 element.

The plate (b) includes 1.0 wt % titanium oxide (TiO₂: AM-15 produced by Taki Chemical Co., Ltd.) as additive 19. A crack was developed in the plate (b) after 288 hours from the start of the test. Thus, the plate (b) has an improved heat resistance over plate Ref. Note that titanium is a group 4 element.

The plate (c) includes 1.0 wt % iron oxide (Fe₂O₃: Fe-C10 produced. by Taki Chemical Co., Ltd.) as additive 19. No crack was developed in the plate (c) even after 1536 hours from the start of the test, indicating that the plate (c) has an improved heat resistance over plate Ref. Note that iron is a group 8 element.

The plate (d) includes 1.0 wt % cerium oxide (CeO₂: B-10 produced by Taki Chemical Co., Ltd.) as additive 19. A crack was developed in the plate (d) after 1152 hours from the start of the test. Thus, the plate (d) has an improved heat resistance over plate Ref. Note that cerium is a rare earth element (group 3 element).

The plate (e) includes 1.0 wt % yttrium oxide (Y₂O₃: produced by Japan Pure Chemical Co. Ltd.) as additive 19. A crack was developed in the plate (e) after 336 hours from the start of the test. Thus, the plate (e) has an improved heat resistance over plate Ref. Note that yttrium is a rare earth element (group 3 element).

The plate (f) includes 1.0 wt % gadolinium oxide (GdO₂O₃: produced by Japan Pure Chemical Co. Ltd.) as additive 19. A crack was developed in the plate (f) after 168 hours from the start of the test. Thus, the plate has an improved heat resistance over plate Ref. Note that gadolinium is a rare earth element (group 3 element).

As described above, the test results in FIG. 5 show that inclusion of an oxide of a transition metal in sealant 13 can improve the heat resistance of sealant 13.

[Specific Examples of Additive: Metal Salt of Transition Metal]

The plates (g) to (i) include, as additive 19, an oxide which includes zirconium soap. The zirconium soap is a metal salt of a transition metal. The plates (g) to (i), specifically, include metallic soap which includes zirconium octoate (NIKKA OCTHIX zirconium, produced by Nihon Kagaku Sanyo Co., Ltd.).

The plate (g) includes 1.0wt % zirconium soap as additive 19. No crack was developed in the plate (g) even after 1536 hours from the start of the test, indicating that the plate (g) has an improved heat resistance over plate Ref.

The plate (h) includes 0.25 wt % zirconium soap as additive 19. A crack was developed in the plate (h) after 768 hours from the start of the test. Thus, the plate (h) has an improved heat resistance over plate Ref.

The plate (i) includes 0.125 wt % zirconium soap as additive 19. A crack was developed in the plate (i) after 384 hours from the start of the test. Thus, the plate (i) has an improved heat resistance over plate Ref.

As described above, the test results in FIG. 5 show that inclusion of a metal salt of a transition metal in sealant 13 can improve the heat resistance of sealant 13. Higher metal salt content of the transition metal produces sealant 13 having greater heat resistance.

Note that the metallic soap which includes zirconium octoate is one example of the metal salt of the transition metal. Sealant 13 may include a metal salt (metallic soap) other than the metallic soap which includes metal octoate, or may include a metal salt (metallic soap) of a transition metal other than zirconium.

[Specific Examples of Additive: Organic Complex of Transition Metal]

The plates (j) and (k) include an organic complex of a transition metal, as additive 19. The plates (j) and (k), specifically, include a zirconium acetylacetone complex (NĀCEM zirconium, produced by Nihon Kagaku Sanyo Co., Ltd.).

The plate (j) includes 0.25 wt % zirconium organic complex as additive 19. A crack was developed in the plate (j) after 336 hours from the start of the test. Thus, the plate (j) has an improved heat resistance over plate Ref.

The plate (k) includes 0.125 wt % zirconium organic complex as additive 19. A crack was developed in the plate (k) after 288 hours from the start of the test. Thus, the plate (k) has an improved heat resistance over plate Ref.

As described above, the test results in FIG. 5 show that inclusion of an organic complex of a transition metal in sealant 13 can improve the heat resistance of sealant 13. Higher organic complex content of the transition metal produces sealant 13 having greater heat resistance.

Note that the acetylacetone complex of zirconium is one example of the organic complex of the transition metal. Sealant 13 may include an organic complex other than acetylacetone complex, or may include an organic complex of a transition metal other than zirconium.

[Mixing of Complex Oxide of Transition Metals]

Sealant 13 may include a complex oxide of transition metals, as additive 19. For example, the plate (l) includes 1.0 wt % complex oxide of zirconium and yttrium ((Y₂O₃)ₓ(ZrO₂)₁₋ₓ: HSY-3.0 produced by Daiichi Kigenso Kagaku Kogyo Co., Ltd.). A crack was developed in the plate (l) after 336 hours from the start of the test. Thus, the plate (l) has an improved heat resistance over plate Ref.

The plate (m) includes 1.0 wt % complex oxide of zirconium and yttrium ((Y₂O₃)ₓ(ZrO₂)₁₋ₓ: Daiichi Kigenso Kagaku Kogyo Co., Ltd., HSY-8.0). A crack was developed in the plate (m) after 336 hours from the start of the test. Thus, the plate (m) has an improved heat resistance over plate Ref.

As described above, the test results in FIG. 5 show that inclusion of the complex oxide of transition metals in sealant 13 can improve the heat resistance of sealant 13.

Note that the complex oxide of zirconium and yttrium is by way of example, and sealant 13 may include a complex oxide of other transition metals.

[Mixing of Oxide of Transition Metal and Metal Salt of Transition Metal]

Sealant 13 may include of the three additives: an oxide of a transition metal; a metal salt of a transition metal; and an organic complex of a transition metal. However, sealant 13 may include two or more of the three. In other words, sealant 13 may include different types of additives 19. Sealant 13 may include, for example, an oxide of a transition metal and a metal salt of a transition metal.

The plate (n) includes, as additive 19, 0.125 wt %, in total, of zirconium oxide (ZrO₂: Zr-C20 produced by Taki Chemical Co., Ltd.) and the metallic soap which includes zirconium octoate (NIKKA OCTHIX zirconium produced by Nihon Kagaku Sangyo Co., Ltd.).

A crack was developed in the plate (n) after 456 hours from the start of the test. Thus, the plate (n) has an improved heat resistance over plate Ref.

As described above, the test result in FIG. 5 shows that inclusion of an oxide of a transition metal and a metal salt of a transition metal in sealant 13 can improve the beat resistance of sealant 13.

In particular,sealant 13 (the plate (n)) that includes the oxide of the transition metal and the metal salt of the transition metal has a greater heat resistance than sealant 13 (the plate (j) that includes only the metal salt of the transition metal at the same additive loading of 0.125 wt %.

[Mixing of Oxide of Transition Metal and Organic Complex of Transition Metal]

Sealant 13 may include, for example, an oxide of a transition metal and an organic complex of a transition metal.

The plate (o) includes, as additive 19, 0.125 wt %, in total, of zirconium oxide (ZrO₂: Zr-C20 produced by Taki Chemical Co., Ltd.) and a zirconium acetylacetone complex (NĀCEM zirconium produced by Nihon Kagaku Sangyo Co., Ltd.).

A crack was developed in the plate (o) after 1152 hours from the start of the test. Thus, the plate (o) has an improved heat resistance over plate Ref.

As described above, the test result in FIG. 5 shows that inclusion of an oxide of a transition metal and an organic complex of a transition metal in sealant 13 can improve the heat resistance of sealant 13.

In particular, sealant 13 (the plate (o)) that includes the oxide of the transition metal and the metal complex of the transition metal has a greater heat resistance than sealant (the plate (k)) that includes only the metal complex of the transition metal at the same additive loading of 0.125 wt %.

[Oxide Content of Transition Metal]

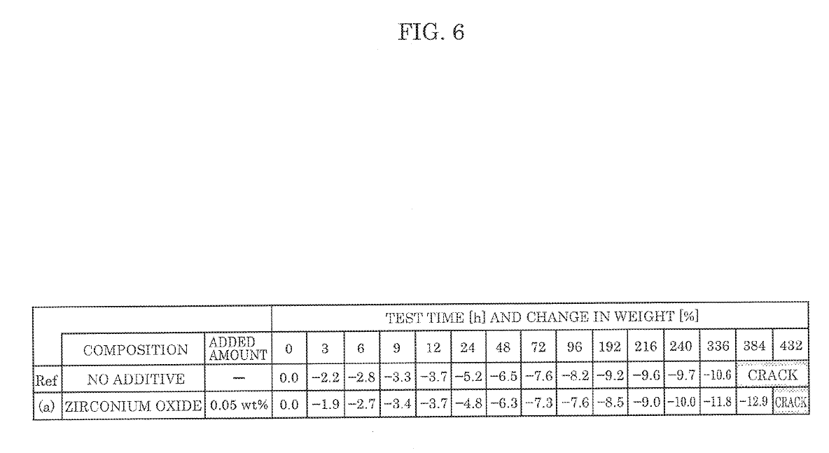

It is contemplated that the greater the additive content is, the more the sealant 13 improves in heat resistance. Thus, the inventors tested, for example, how much oxide of the transition metal is required in sealant 13 to significantly improve the heat resistance of sealant 13. FIG. 6 is a second diagram showing test results on the heat resistance of sealant 13.

FIG. 6 shows comparison in heat resistance between plate Ref and the plate (a) which includes KJR9025HH (silicone resin), produced by Shin-Etsu Chemical Co., Ltd., as a base material, wherein plate Ref is free from additive 19, whereas the plate (a) includes zirconium oxide (ZrO₂: Daiichi Kigenso Kagaku Kogyo Co., Ltd., RC-100) as additive 19.

As illustrated in FIG. 6, it can be said that the plate (a) can have a heat resistance greater than a heat resistance of Ref if the plate (a) includes at least 0.05 wt % zirconium oxide. Thus, sealant 13 may include 0.05 wt % or more oxide of a transition metal in order to improve the heat resistance. Note that the oxide of the transition metal that can be included in sealant 13 is less than 100 wt %.

[Effects]

As described above, light-emitting apparatus 10 includes substrate 11, LED chips 12 on substrate 11, and sealant 13 which seals LED chips 12. Sealant 13 includes at least 0.05 wt % oxide of a transition metal as additive 19 for inhibiting deterioration of base material 18 of sealant 13 LED chip 12 is an example of a light-emitting.

This allows light-emitting apparatus 10 to have sealant 13 having an improved heat resistance.

Moreover, the transition metal may be a group 4 element.

As such, light-emitting apparatus 10 includes an oxide of a group 4 element in sealant 13, and thereby sealant 13 has an improved heat resistance.

Moreover, the group 4 element may be titanium or zirconium.

As such, light-emitting apparatus 10 includes an oxide of titanium or an oxide of zirconium in sealant 13, and thereby sealant 13 has an improved heat resistance.

Moreover, the transition metal may be a rare earth element.

As such, light-emitting apparatus 10 includes an oxide of a rare earth element in sealant 13, and thereby sealant 13 has an improved heat resistance.

Moreover, the transition metal may be yttrium, cerium, or gadolinium.

As such, light-emitting apparatus 10 includes an oxide of yttrium, an oxide of cerium, or an oxide of gadolinium in sealant 13, and thereby sealant 13 has an improved heat resistance.

Additionally or alternatively, sealant 13 may include at least one of a metal salt of a transition metal and an organic complex of a transition metal, as additive 19 for inhibiting deterioration of base material 18 of sealant 13.

This allows light-emitting apparatus 10 to have sealant 13 having an improved heat resistance.

Moreover, the metal salt of the transition metal may be a metallic soap which includes metal octoate.

As such, light-emitting apparatus 10 includes the metallic soap, which includes metal octoate, in sealant 13, and thereby sealant 13 has an improved heat resistance.

Moreover, the organic complex of the transition metal may be an acetylacetone complex.

As such, light-emitting apparatus 10 includes the acetylacetone complex of the transition metal in sealant 13, and thereby sealant 13 has an improved heat resistance.

Moreover, additive 19 may include at least one of a metal salt of zirconium and a zirconium organic complex.

As such, light-emitting apparatus 10 includes at least one of a metal salt of zirconium and a zirconium organic complex in sealant 13, and thereby sealant 13 has an improved heat resistance.

Moreover, additive 19 may further include an oxide of a transition metal.

This allows the improvement of sealant 13 in heat resistance and the reduction of the amount of the additive, as illustrated in the plates (n) and (o) of FIG. 5.

Moreover, sealant 13 may further include yellow phosphor 14 which is excitable by light emitted by LED chips 12, and additive 19 may not be excitable by the light emitted by LED chips 1. Yellow phosphor 14 is one example of the phosphor.

As, such, typically, additive 19 does not have wavelength conversion capability (emits no light).

### Embodiment 2

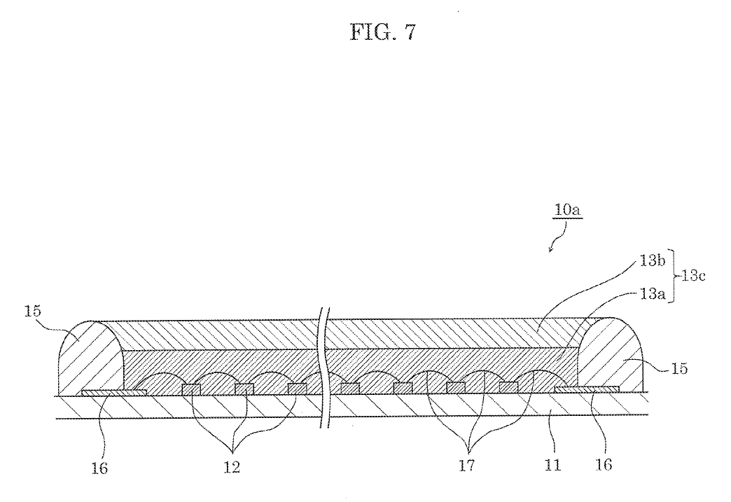

In the following, a light-emitting apparatus according to Embodiment 2 of the present disclosure is described. Note that the light-emitting apparatus according Embodiment 2 has the same configuration as light emitting apparatus 10 according to Embodiment 1, except for the sealant. Thus, the description is given, focusing on a structure of the sealant, with reference to a cross-sectional view of the light-emitting apparatus according to Embodiment 2. The same reference sign is used to refer to substantially the same configuration as light-emitting apparatus 10 and the description is omitted. FIG. 7 is a cross-sectional view of the light-emitting apparatus according to Embodiment 2. Note that FIG. 7 is a cross-sectional view corresponding to the cross section taken along the line IV-IV in FIG. 2.

A feature of light-emitting apparatus 10a according to Embodiment 2 is that sealant 13c has a two-layer structure. Sealant 13c, specifically, includes first sealing layer 13a and second sealing layer 13b.

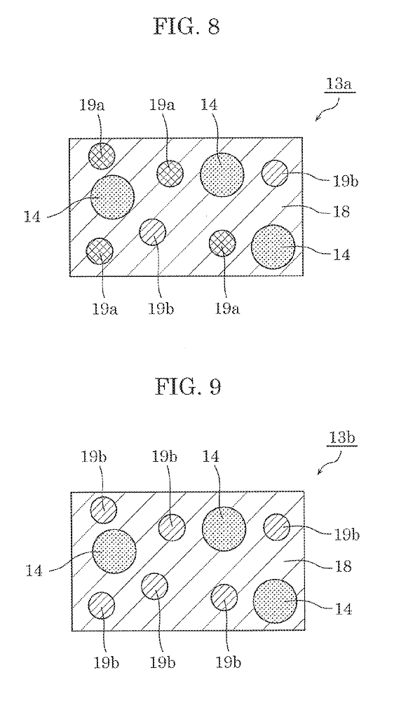

Initially, first sealing layer 13a is described with further reference to FIG. 8. FIG. 8 is a schematic view illustrating a structure of first sealing layer 13a.

First sealing layer 13a seals LED chips 12. As illustrated in FIG. 8, first sealing layer 13a includes base material 18, yellow phosphor 14, first additive 19a, and second additive 19b. First sealing layer 13a may include a filler. Note that FIG, 8 is schematic illustration and does not strictly illustrate the shapes and particle sizes of yellow phosphor 14, first additive 19a, and second additive 19b.

Base material 18 is a light-transmissive resin material, specifically, a methyl-based silicone resin. However, base material 18 may be an epoxy resin or a urea resin, for example.

First additive 19a is, for example, a white or colorless oxide of a transition metal, and included in sealant 13c to inhibit deterioration of base material 18. Note that first additive 19a may be a white or colorless metal salt of a transition metal or may be a white or colorless organic complex of a transition metal.

Second additive 19b is, for example, a metal salt of a transition metal or an organic complex of a transition metal as described in the above embodiments. Second additive 19b is included in sealant 13c to inhibit deterioration of base material 18. In Embodiment 2, second additive 19b is, for example, pale yellow in color. In other words, second additive 19b absorbs more blue light emitted by LED chips 12 than first additive 19a. Stated differently, second additive 19b have a capability of higher absorption (absorption coefficient, absorbance) of the light emitted by LED chips 12 than first additive 19a. Note that second additive 19b may have a capability of higher absorption of blue light emitted by LED chips 12 than first additive 19a, and may be a pale-yellow oxide of a transition metal. Note that the color of second additive 19b is not limited to pale yellow, and may be any color (neither while nor colorless) that is different from first additive 19a, for example.

First sealing layer 13a includes second additive 19b less in amount than first additive 19a. First sealing layer 13a may be free from second additive 19b.

First sealing layer 13a seals bonding wires 17, in addition to sealing LED chips 12. In other words, first sealing layer 13a serves to protect LED chips 12 and bonding wires 17 from refuse, moisture, or external force etc.

First sealing layer 13a also serves as a wavelength conversion material. A portion of blue light emitted by LED chip 12 is wavelength-converted into yellow light by yellow phosphor 14 included in first sealing layer 13a. Then, blue light not absorbed in yellow phosphor 14 and the yellow light obtained by the wavelength conversion by yellow phosphor 14 are diffused and mixed in first sealing layer 13a. This allows white light to be emitted from first sealing layer 13a (sealant 13c).

Next, second sealing layer 13b is described, with further reference to FIG. 9. FIG. 9 is a schematic view illustrating a structure of second sealing layer 13b.

Second sealing layer 13b is positioned over first sealing layer 13a. As illustrated in FIG. 9, second sealing layer 13b includes base material 18, yellow phosphor 14, and second additive 19b. Second sealing layer 13b does not include but may include first additive 19a. Second sealing layer 13b may include a filler. Note that. FIG. 9 is a schematic illustration and does not strictly illustrate the shapes and particle sizes of yellow phosphor 14 and second additive 19b.

In Embodiment 2, base material 18 in second sealing layer 13b is formed using a material (sealing material) that is the same as a material from which base material 18 in first sealing layer 13a is formed. In this case, an interface is formed between first sealing layer 13a and second sealing layer 13b as the sealing material for first sealing layer 13a and the sealing material for second sealing layer 13b are cured after application. Doing so reduces loss of light attributed to formation of the interface, thereby yielding an advantageous effect of inhibiting reduction of the efficiency of light-emitting apparatus 10a in extracting light.

Note that base material 18 of first sealing layer 13a and base material 18 of second sealing layer 13b may be formed using different materials. For example, first sealing layer 13a may be formed using a methyl-based silicone resin and second sealing layer 13b may be formed using a phenyl-based silicone resin.

Second sealing layer 13b is a portion of sealant 13 which is in contact with the atmosphere, and serves as a protective layer for inhibiting oxidative degradation of first sealing layer 13a. The concentration of second additive 19b in second sealing layer 13b is greater than the concentration of second additive 19b in first sealing layer 13a.

### Effects of Embodiment 2

As described above, in light-emitting apparatus 10a, the additive includes first additive 19a and second additive 19b, the second additive 19b being configured to absorbs more the light emitted by LED chips 12 than first additive 19a. Sealant 13c includes first sealing layer 13a which seals LED chips 12, and second sealing layer 13b which is above first sealing layer 13a. First sealing layer 13a contains yellow phosphor 14 which is excitable by light emitted by LED chips 12.

Here, the concentration of second additive 19b in second sealing layer 13b is greater than the concentration of second additive 19b in first sealing layer 13a. In the following, advantageous effects of such a configuration are described.

A portion of blue light emitted by LED chips 12 is wavelength-converted by yellow phosphor 14 included in first sealing layer 13a into yellow light, before reaching second sealing layer 13b. The yellow light is poorly absorbed into second additive 19b. Thus, the absorption of light into second additive 19b (blue light) is suppressed and heat generation by second additive 19b is reduced. Hence, the heat resistance of sealant 13c improves.

The two-layer structure in which the concentration of second additive 19b is altered as such is useful when multiple types of additives are added to sealant 13c. For example, as described in Embodiment 1, the use of an oxide of a transition metal and one of a metal salt of a transition metal and an organic complex of a transition metal may improve the heat resistance of sealant 13 and also reduce the amount of the additives (see the plates (n) and (o) in FIG. 5). In such a case, the two-layer structure in which the concentration of second additive 19b is altered can further increase the heat resistance of sealant 13c.

Note that the laminated structure of sealant 13c included in light-emitting apparatus 10a is by way of example. For example, another layer may be disposed between first sealing layer 13a and second sealing layer 13b. While the primary material of each of the layers in the laminated structure of light-emitting apparatus 10a is illustrated in. Embodiment 2, each layer in the laminated structure may include any other material to an extent that can achieve the same feature as that of light-emitting apparatus 10a described above.

### Embodiment 3

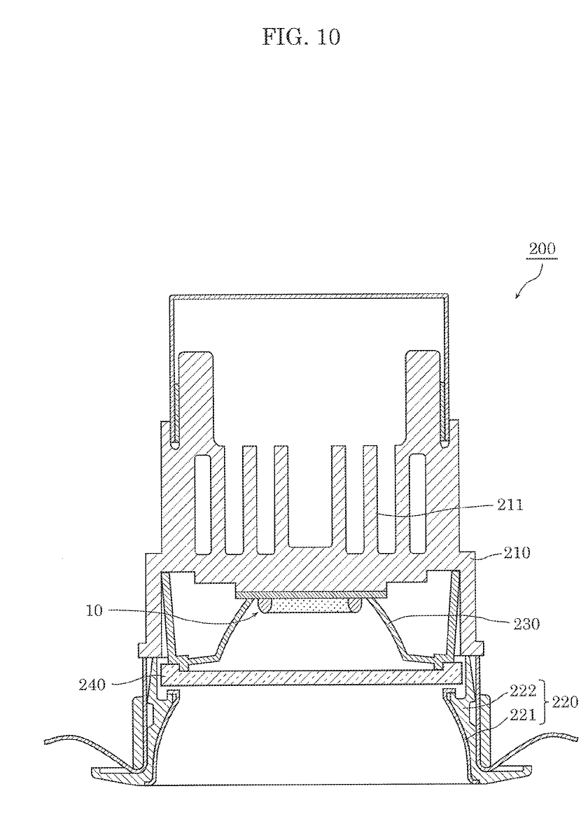

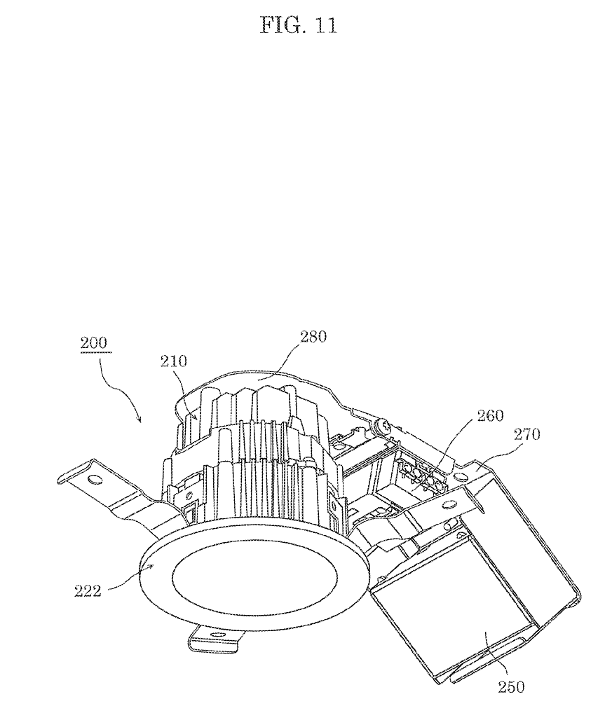

Next, illumination apparatus 200 according to Embodiment 3 of the present disclosure is described, with reference to FIGS. 10 and 11. FIG. 10 is a cross-sectional view of illumination apparatus 200 according to Embodiment 3. FIG. 11 is an external perspective view of illumination apparatus 200 and its peripheral components according to Embodiment 3.

As illustrated in FIGS. 10 and 11, illumination apparatus 200 according to Embodiment 3 is, for example, a built-in illumination apparatus, such as a downlight, which is recessed in the ceiling in a house, for example, and emits light in a down direction (to a hallway, a wall, etc.).

Illumination apparatus 200 includes light-emitting apparatus 10 Illumination apparatus 200 further includes a body having a generally-closed-end cylindrical shape, reflector 230, and light-transmissive panel 240 which are disposed on the body. The body is configured by coupling base 210 and frame member 220 with each other.

Base 210 is a mounting base on which light-emitting apparatus 10 is mounted, and serves also as a heat sink for dissipating heat generated by light-emitting apparatus 10. Base 210 is formed in a substantially cylindrical shape, using a metallic material. Base 210 is an aluminum die cast product in Embodiment 3.

On top of base 210 (a portion on the ceiling side), heat dissipating fins 211 extending upward are disposed, spaced apart at regular intervals along one direction. This allows efficient dissipation of the heat generated by light-emitting apparatus 10.

Frame member 220 includes cone 221 is a substantially-cylindrical shape, and includes a reflective inner surface and frame body 222 on which cone 221 is mounted. Cone 221 is formed using a metallic material. Cone 221 can be formed by drawing or press forming of aluminum alloy, for example. Frame body 222 is formed, using a rigid resin material or a metallic material. Frame member 220 is secured by frame body 222 mounted on base 210.

Reflector 230 is a ring-shaped (a funnel-shaped) reflective member having internal reflectivity. Reflector 230 can be formed using a metallic material, such as aluminum, for example. Note that reflector 230 may also be formed using a rigid white resin material, rather than using a metallic material.

Light-transmissive panel 240 is a light-transmissive member that is light diffusible and light transmissive. Light-transmissive panel 240 is a flat plate disposed between reflector 230 and frame member 220, and mounted on reflector 230. Light-transmissive panel 240 can be formed in a disk shape, using a transparent resin material, such as acrylic or polycarbonate.

Note that illumination apparatus 200 may not include light transmissive panel 240. Without light-transmissive panel 240, illumination apparatus 200 can improve the luminous flux of light emitted from illumination apparatus 200.

Also as shown in FIG. 11, illumination apparatus 200 is connected to lighting apparatus 250 which supplies light-emitting apparatus 10 with power for causing light-emitting apparatus 10 to emit light, and terminal base 260 which relays an alternating-current power from mains supply to lighting apparatus 250. Lighting apparatus 250, specifically, converts alternating-current power that is relayed from terminal base 260 into direct-current power and outputs the direct-current power to light-emitting apparatus 10.

Lighting apparatus 250 and terminal base 260 are secured to mounting plate 270 that provided separately from the body. Mounting plate 270 is formed by bending a rectangular plate member which includes a metallic material. Lighting apparatus 250 is secured onto the undersurface of one end portion of mounting plate 270, and terminal base 260 is secured onto the undersurface of the other end portion. Mounting plate 270 is connected plate 280 secured on top of base 210 of the body.

As described above, illumination apparatus 200 includes light-emitting apparatus 10 and lighting apparatus 250 which supplies light-emitting apparatus 10 with power for causing light-emitting apparatus 10 to emit light. This achieves sealant 13 having an improved heat resistance in illumination apparatus 200.

Note that illumination apparatus 200 may include light-emitting apparatus 10a, in place of light-emitting apparatus 10. In this case also, sealant 13c in illumination apparatus 200 has an improved heat resistance.

While the downlight is illustrated as the illumination apparatus according to the present disclosure in Embodiment 3, the present disclosure may be implemented as any other illumination apparatus, such as a spot light.

### Other Embodiments

While the light-emitting apparatus and the illumination apparatus have been described above, the present disclosure is not limited to the embodiments described above.

For example, while the light-emitting apparatus having a COB structure is described in the above embodiments, the present disclosure is also applicable to a light-emitting apparatus that has an SMD structure. An SMD light-emitting apparatus (a light-emitting element) includes, for example, a resin housing having a recess, an LED chip mounted on the recess, and a sealing material (a phosphor-containing resin) encapsulated in the recess.

Moreover, while in the above embodiments, the light-emitting apparatus provides white light by a combination of the yellow phosphor and the LED chip which emits blue light, the configuration for providing white light is not limited thereto. For example, a phosphor-containing resin which includes red phosphor and green phosphor and an LED chip which emits blue light or violet light may be combined.

Moreover, in the above embodiments, the Chip To Chip connection is established, by the bonding wires, between the LED chips mounted on the substrate. The LED chips, however, may be connected to the lines (a metal film) on the substrate by the bonding wires, and electrically connected to one another via the lines.

Moreover, in the above embodiments, the LED chips are illustrated as light-emitting elements included in the light-emitting apparatus. However, the light-emitting element may be a semiconductor light-emitting element, such as a semiconductor laser, or a solid-state light-emitting device, such as an electro-luminescent (EL) element, including, for example, an organic EL element and an inorganic EL element.

Moreover, the light-emitting apparatus may include two or more types of the light-emitting elements having different emission colors. For example, in addition to the LED chip which emits blue light, the light-emitting apparatus may include an LED chip which emits red light, for the purposes of enhancing color rendering.

In other instances, various modifications to the embodiments according to the present disclosure described above that may be conceived by those skilled in the art and embodiments implemented by any combination of the components and functions shown in the embodiments are also included within the scope of the present disclosure, without departing from the spirit of the present disclosure.

What is claimed is:

1. A light-emitting apparatus, comprising:
a substrate;
a light-emitting element on the substrate: and
a sealant which seals the light-emitting element, wherein
the sealant includes at least 0.05 wt % oxide of a transition metal as an additive for inhibiting deterioration of a base material of the sealant.

2. The light-emitting apparatus according to claim 1, wherein
the transition metal is a group 4 element.

3. The light-emitting apparatus according to claim 2, wherein
the transition metal is titanium or zirconium.

4. The light-emitting apparatus according to claim 1, wherein
the transition metal is a rare earth element.

5. The light-emitting apparatus according to claim 4, wherein
the transition metal is yttrium, cerium, or gadolinium.

6. The light-emitting apparatus according to claim 1, wherein
the sealant further includes phosphor which is excitable by light emitted by the light-emitting element, and
the additive is not excitable by the fitted by the light-emitting element.

7. The light-emitting apparatus according to claim 6, wherein
the light-emitting element is configured to emit the light of a first color,
the phosphor is configured to wavelength-convert a first portion of the light emitted by the light-emitting element into second light of a second color, and
the sealant is configured to diffuse and mix a second portion of the light emitted by the light-emitting element which is not absorbed by the phosphor and the second light to emit a third light of a third color, the third color being different from the first color and the second color.

8. The light-emitting apparatus according to claim 1, wherein
the additive includes a first additive and a second additive, the second additive being configured to absorb more light emitted by the light-emitting element than the first additive,
the sealant includes a first sealing layer which seals the light-emitting element and a second sealing layer above the first sealing layer,
the first sealing layer contains phosphor which is excitable by the light emitted by the light-emitting element, and
a concentration of the second additive in the second sealing layer is greater than a concentration of the second additive in the first sealing layer.

9. The light-emitting apparatus according to claim 1, wherein
the sealant further includes at least one of a metal salt of a transition metal and an organic complex of a transition metal.

10. The light-emitting apparatus according to claim 1, wherein
the additive includes an oxygen storage capacity and a property of chemically bonding with silicon monoxide.

11. The light-emitting apparatus according to claim 1, wherein
the additive increases a heat resistance of the sealant.

12. An illumination apparatus, comprising:
the light-emitting apparatus according to claim 1; and
a lighting apparatus which supplies the light-emitting apparatus with power for causing the light-emitting apparatus to emit light.

13. A light-emitting apparatus, comprising:
a substrate;
a light-emitting element on the substrate; and
a sealant which seals the light-emitting element, wherein
the sealant includes at least one of a metal salt of a transition metal and an organic complex of a transition metal, as an additive for inhibiting deterioration of a base material of the sealant.

14. The light-emitting apparatus according claim 13, wherein
the sealant includes the metal salt of the transition metal, and
the metal salt of the transition metal is a metallic soap which includes metal octoate.

15. The light-emitting apparatus according to claim 13, wherein
the sealant includes the organic complex of the transition metal, and
the organic complex of the transition metal is an acetylacetone complex.

16. The light-emitting apparatus according to claim 13, wherein
the additive includes at least one of a metal salt of zirconium and a zirconium organic complex.

17. The light-emitting apparatus according to claim 13, wherein the additive further includes an oxide of a transition metal.

18. A light-emitting apparatus, comprising:
a substrate;
a light-emitting element on the substrate;
a first sealing layer which seals the light-emitting element and includes a first additive and a second additive; and
a second sealing layer which is above the first sealing layer and includes the second additive, wherein
the first additive is an oxide of a transition metal, and
the second additive is a metal salt of a transition metal or an organic complex of a transition metal.

19. The light-emitting apparatus according to claim 18, wherein
the second additive has a higher absorption capability of a predetermined color of light than the first additive.

20. The light-emitting apparatus according to claim 18, wherein
a concentration of the second additive in the second sealing layer is greater than a concentration of the second additive in the first sealing layer.
